(19) United States
(12) Patent Application Publication
(10) Pub. No.: US 2026/0082869 A1
(43) Pub. Date: Mar. 19, 2026

(54) SEMICONDUCTOR DEVICE AND BONDING FAILURE TEST METHOD THEREOF

(71) Applicant: Taiwan Semiconductor Manufacturing Company, Ltd., Hsinchu (TW)

(72) Inventors: Chi-Hui LAI, Hsinchu (TW); Tse-Wei LIAO, Hsinchu (TW); Yang-Che CHEN, Hsinchu (TW); Hsiang-Tai LU, Hsinchu (TW); WEI-RAY LIN, Hsinchu (TW)

(73) Assignee: Taiwan Semiconductor Manufacturing Company, Ltd., Hsinchu (TW)

(21) Appl. No.: 18/885,872

(22) Filed: Sep. 16, 2024

(51) Int. Cl. H01L 21/66; G01R 31/28

(52) U.S. Cl. CPC H10P 74/273; G01R 31/2884

(57) ABSTRACT

A semiconductor device includes a bottom die and a top die. The includes a first test pad set, a second test pad set, a first bottom BPM set electrically connected with the first test pad set, and a second bottom BPM set electrically connected with the second test pad set. The top die includes a first top BPM set bonding to the first bottom BPM set, and a second top BPM set bonding to the second bottom BPM set. The first test pad set has a test pad area, the first bottom BPM set has a first bottom BPM area, and the second bottom BPM set has a second bottom BPM area. The test pad area is greater than the first bottom BPM area and the second bottom BPM area, and the first bottom BPM area is equal to or less than the second bottom BPM area.

### BACKGROUND

A CMP (Chemical-Mechanical Planarization) process for BPM (bonding pad metal) is high risk to induce galvanic corrosion. However, this corrosion is not easily caught by in-line defect tool at process stage. Thus, proposing a new technique to improve the aforementioned problems is one of the goals of industry players in this field.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of a semiconductor device according to an embodiment of the present disclosure;

FIG. 1B illustrates a schematic diagram of a cross-sectional view of the semiconductor device in FIG. 1A along a direction 1B-1B′;

FIG. 2A illustrates a schematic diagram of a semiconductor device according to another embodiment of the present disclosure;

FIG. 2B illustrates a schematic diagram of a cross-sectional view of the semiconductor device in FIG. 2A along a direction 2B-2B′;

FIGS. 3A to 3D illustrate test processes of a bonding failure test method of the semiconductor device in FIG. 2B.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

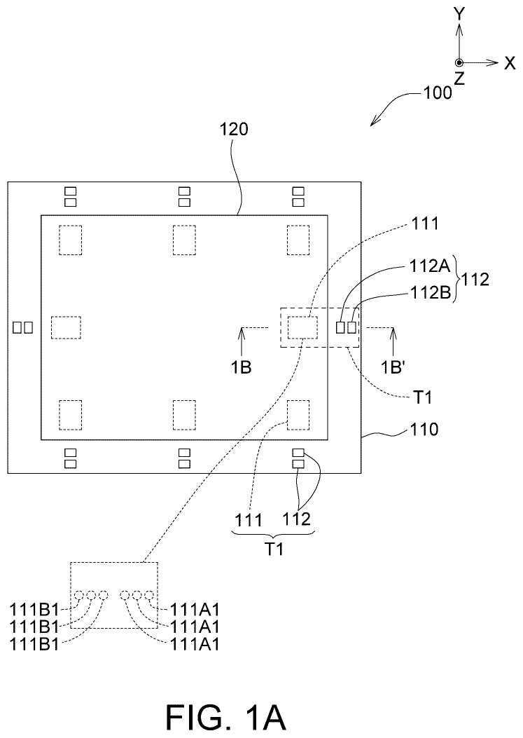

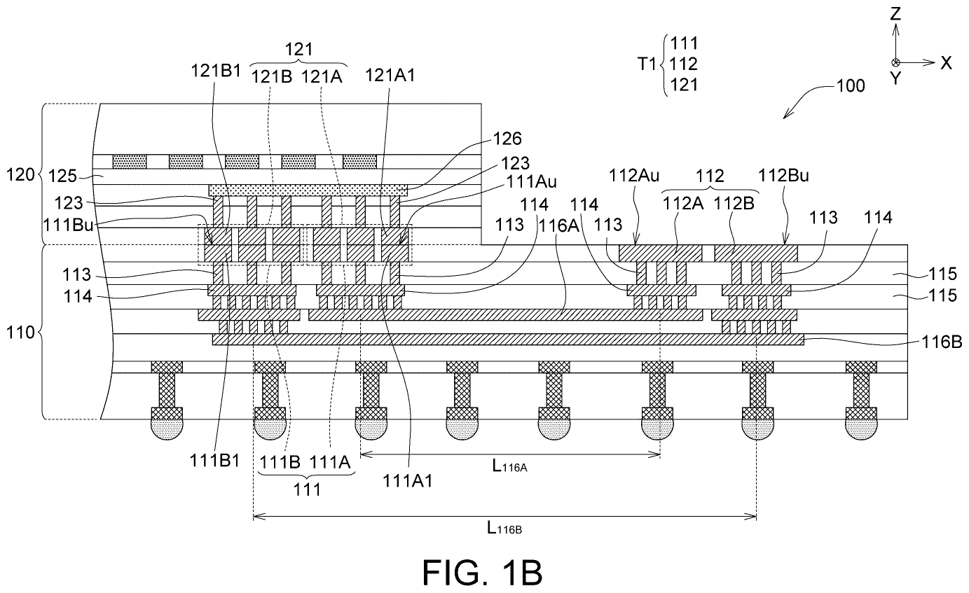

Referring to FIGS. 1A and 1B, FIG. 1A illustrates a schematic diagram of a semiconductor device 100 according to an embodiment of the present disclosure, and FIG. 1B illustrates a schematic diagram of a cross-sectional view of the semiconductor device 100 in FIG. 1A along a direction 1B-1B′.

As illustrated in FIG. 1B, the semiconductor device 100 includes a bottom die 110 and a top die 120. The bottom die 110 includes a bottom bonding pad metal (BPM) set 111 and a test pad set 112. The top die 120 includes a top BPM set 121. The bottom BPM set 111 is electrically connected with the test pad set 112. The top BPM set 121 is bonded to the bottom BPM set 111. A WAT (Wafer Acceptance Test) may probe the test pad set 112 to detect a failure mode of the semiconductor device 100. The failure mode (or chain open) may include a defect, a galvanic and a non-bond.

In terms of the defect mode, the particles remaining on an end surface of BPM causes the failure of the electrical connection between the BPM of the bottom die 110 and the BPM of the top die 120, and such failure mode is called “defect”. In terms of the galvanic mode, a recess (metal loss or Cu loss) formed in an end surface of the BPM after CMP cause the failure of the electrical connection between the BPM of the bottom die 110 and the BPM of the top die 120, and such failure mode is called “galvanic (or galvanic corrosion)”. In terms of the non-bond mode, a poor alignment process (for example, a poor temperature, a poor pressure, etc.) between the bottom die 110 and the top die 120 causes the failure of the electrical connection between the BPM of the bottom die 110 and the BPM of the top die 120, and such failure mode is called “non-bond”.

As illustrated in FIGS. 1A and 1B, the top die 120 has an area (in XY plane) smaller than that of the bottom die 110, and thus an edge region of an upper surface of the bottom die 110 is not covered by the top die 120. The test pad set 112 is exposed from the edge region of an upper surface of the bottom die 110 for being probed.

As illustrated in FIG. 1A, the bottom BPM set 111, the test pad set 112 and the top BPM set 121 form one test group T1. The semiconductor device 100 may include at least one test group T1. One of the test groups T1 may be disposed adjacent to one of a plurality of lateral edges of the top die 120, another of the test groups T1 may be disposed adjacent to one of a plurality of corners of the top die 120. The test group T1 which is disposed adjacent to the corner of the top die 120 may detect the galvanic (the galvanic tends to occur in the corner).

As illustrated in FIG. 1B, the test pad set 112 may be electrically connected with the bottom BPM set 111 through at least one conductive portion (for example, via, trace, etc.). Furthermore, the bottom die 110 further includes a plurality of bottom bonding pad vias (BPVs) 113, a plurality of bottom traces 114, a plurality of bottom dielectric layers 115, a first connection trace 116A and a second connection trace 116B.

The BPM and the BPV may be formed of, for example, a copper (Cu) or alloy combination thereof. The bottom dielectric layers 115 may be formed of, for example, oxide, etc.

As illustrated in FIG. 1B, the bottom dielectric layers 115 are stacked to each other. The bottom BPM set 111 includes an output bottom BPM 111A and an input bottom BPM 111B. The output bottom BPM 111A and the input bottom BPM 111B are formed in or on the topmost one of the bottom dielectric layers 115. The output bottom BPM 111A includes a plurality of output bottom BPM pad 111A1, the input bottom BPM 111B includes a plurality of input bottom BPM pad 111B1. In the present embodiment, the number of the output bottom BPM pad 111A1 is equal to or different from the number of the input bottom BPM pad 111B1.

As illustrated in FIG. 1A, the output bottom BPM pads 111A1 may arranged in an array of n1×m1, wherein each of n1 and m1 may be a positive integer equal to or greater than one. Similarly, the input bottom BPM pads 111B1 may arranged in an array of n2×m2, wherein each of n2 and m2 may be a positive integer equal to or greater than one. The n1 and n2 may be equal or different in value, and/or m1 and m2 may be equal or different in value. In another embodiment, the output bottom BPM pads 111A1 may be irregularly arranged, and/or the input bottom BPM pads 111B1 may be irregularly arranged.

As illustrated in FIG. 1B, the test pad set 112 includes an input test pad 112A and an output test pad 112B. The input test pad 112A and the output test pad 112B are formed in or on the topmost bottom dielectric layer 115.

As illustrated in FIG. 1B, the bottom BPVs 113 are formed in one of the dielectric layers 115 to connect with the test pad set 112 and the top BPM set 121. The first connection trace 116A connects the input test pad 112A of the test pad set 112 with the output bottom BPM 111A of the bottom BPM set 111 through the bottom BPVs 113 and the bottom traces 114. The second connection trace 116B connects the output test pad 112B of the test pad set 112 with the input bottom BPM 111B of the bottom BPM set 111 through the bottom BPVs 113 and the bottom traces 114.

As illustrated in FIG. 1B, the top BPM set 121 includes an input top BPM 121A and an output top BPM 121B. The top die 120 further includes a plurality of top BPVs 123, a connection trace 126 and a plurality of top dielectric layers 125. The top dielectric layers 125 are stacked to each other. The top dielectric layer 125 may be formed of, for example, oxide, etc. The input top BPM 121A and the output top BPM 121B are formed in or on the bottommost top dielectric layer 125. The input top BPM 121A includes a plurality of input top BPM pads 121A1, the output top BPM 121B includes a plurality of output top BPM pad 121B1. In the present embodiment, the number of the input top BPM pad 121A1 is equal to the number of the output top BPM pad 121B1. In the present embodiment, each input top BPM pad 121A1 is directly bonded to the corresponding output bottom BPM pad 111A1, and each output top BPM pad 121B1 is directly bonded to the corresponding input bottom BPM pad 111B1 by using, for example, hybrid bonding technique.

As illustrated in FIG. 1B, the top BPVs 123 penetrate the corresponding dielectric layers 125 to connect the connection trace 126. The connection trace 126 connects the first top BPM 121A with the second top BPM 121B through the top BPVs 123. In an embodiment, the connection trace 126 may be formed of aluminum. The top dielectric layer 125 and the bottom dielectric layer 115 may be bonded to each other by using, for example, hybrid bonding technique. The bonding between the dielectric layers of the bottom die 110 and the top die 120 and the bonding between the BPMs of the bottom die 110 and the top die 120 may be performed in the same bonding process.

As illustrated in FIG. 1B, when the WAT probe the test pad set 112, a test signal (for example, voltage or current) is send to the input test pad 112A and returned from the output test pad 112B through the first connection trace 116A, the output bottom BPM 111A, the input top BPM 121A, the connection trace 126, the output top BPM 121B, the input bottom BPM 111B and the second connection trace 116B in order. The failure mode may be determined by reading a return signal from the output test pad 112B.

As illustrated in FIG. 1B, the output bottom BPM 111A of the bottom BPM set 111 has a bottom BPM area along XY plane, and the input test pad 112A has a test pad area along XY plane. The bottom BPM area is the sum of an area of an end surface 111Au, along XY plane, of each output bottom BPM pad 111A1. The test pad area is an area of an end surface 112Au, along XY plane, of the input test pad 112A. In an embodiment, a ratio of the bottom BPM area to the test pad area may be less than 1/25, and a distance L_{116A} of the input test pad 112A and the output bottom BPM 111A may be greater than 10000 micrometers (μm). The end surface 112Au of the input test pad 112A is, for example, a rectangle, and the test pad area of the end surface 112Au of the input test pad 112A is, for example, 3500 μm² (for example, 50 μm×70 μm). The output test pad 112B includes the features the same as or similar to that of the input test pad 112A. In an embodiment, the distance L_{116A} is the distance (in X-axis) from a geometric center of the shape (in XY plane) of the input test pad 112A to a geometric center of the shape (in XY plane) of the output bottom BPM 111A. Similarly, the input bottom BPM 111B of the bottom BPM set 111 has a bottom BPM area along XY plane, and the output test pad 112B has a test pad area along XY plane. The bottom BPM area is the sum of an area of an end surface 111Bu, along XY plane, of each input bottom BPM pad 111B1. The test pad area is an area of an end surface 112Bu, along XY plane, of the input test pad 112A. In an embodiment, a ratio of the bottom BPM area to the test pad area is less than 1/25, and a distance L_{116B} of the output test pad 112B and the input bottom BPM 111B may be greater than 10000 μm. In an embodiment, the distance L_{116B} is the distance (in X-axis) from a geometric center of the shape (in XY plane) of the output test pad 112B to a geometric center of the shape (in XY plane) of the input bottom BPM 111B. In addition, depending on the positions of the input test pad 112A, the output test pad 112B, the output bottom BPM 111A and the input bottom BPM 111B, the distance L_{116A} may be equal to, less than or greater than the distance L_{116B}.

Due to the design of the ratio and/or the distance, the failure mode (at least including the defect, the galvanic and the non-bond) may be determined by reading and analyzing the return signal from the output test pad 112B.

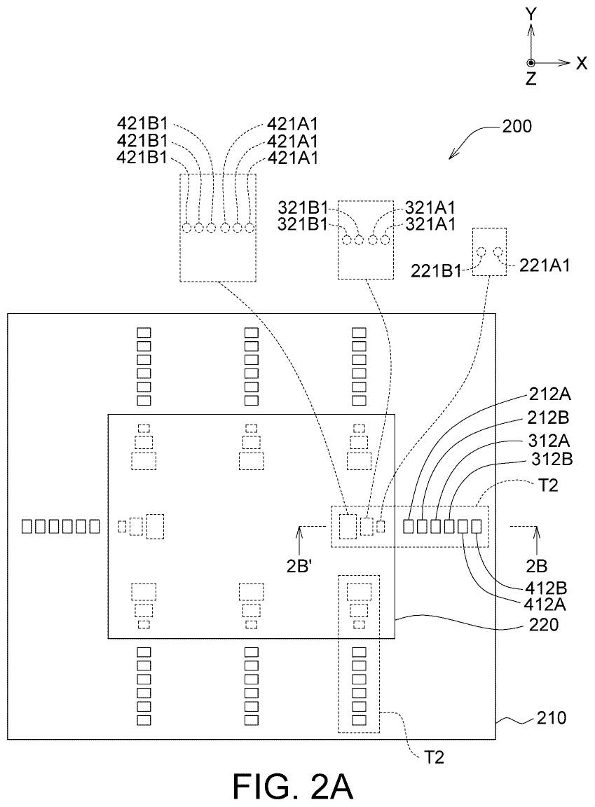

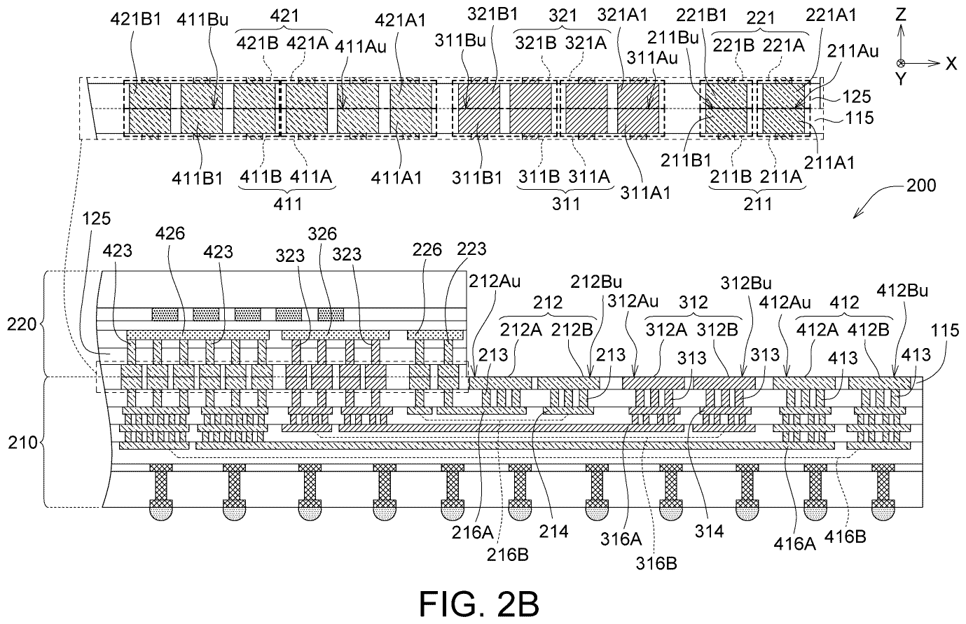

Referring to FIGS. 2A and 2B, FIG. 2A illustrates a schematic diagram of a semiconductor device 200 according to an embodiment of the present disclosure, and FIG. 2B illustrates a schematic diagram of a cross-sectional view of the semiconductor device 200 in FIG. 2A along a direction 2B-2B′.

As illustrated in FIG. 2B, the semiconductor device 200 includes a bottom die 210 and a top die 220. The bottom die 210 includes a first bottom BPM set 211, a first test pad set 212, a second bottom BPM set 311, a second test pad set 312, a third bottom BPM set 411, a third test pad set 412. The top die 220 includes a first top BPM set 221, a second top BPM set 321 and a third top BPM set 421. The first bottom BPM set 211 is electrically connected with the first test pad set 212. The first top BPM set 221 is bonded to the first bottom BPM set 212. The WAT may probe the first test pad set 212 to detect a failure mode of the semiconductor device 200. The failure mode may include the defect, the galvanic and the non-bond.

As illustrated in FIG. 2A, the first bottom BPM set 211, the second bottom BPM set 311, the third bottom BPM set 411, the first test pad set 212, the second test pad set 312, the third test pad set 412, the first top BPM set 221, the second top BPM set 321 and the third top BPM set 421 may form one test group T2. The semiconductor device 200 may include at least one test group T2. One of the test groups T2 may be disposed adjacent to one of a plurality of lateral edges of the top die 220, another of the test groups T2 may be disposed adjacent to one of a plurality of corners of the top die 220. The test group T2 which is disposed adjacent to the corner of the top die 220 may detect the galvanic (the galvanic tends to occur in the corner). In addition, the first test pad set 212, the second test pad set 312 and the third test pad set 412 may arranged in a row (for example, in X-axis) or a column (for example, in Y-axis). In another embodiment, the first test pad set 212, the second test pad set 312 and the third test pad set 412 may be irregularly arranged.

As illustrated in FIG. 2B, the bottom die 210 further includes a plurality of the bottom dielectric layers 115, a plurality of bottom BPVs 213, a plurality of bottom BPVs 313, a plurality of bottom BPVs 413, a first connection trace 216A, a second connection trace 216B, a first connection trace 316A, a second connection trace 316B, a first connection trace 416A and a second connection trace 416B.

As illustrated in FIG. 2B, the first bottom BPM set 211 includes an output bottom BPM 211A and an input bottom BPM 211B. The output bottom BPM 211A and the input bottom BPM 211B are formed in or on the topmost bottom dielectric layer 115. The output bottom BPM 211A includes at least one output bottom BPM pad 211A1, the input bottom BPM 111B includes at least one input bottom BPM pad 211B1. In the present embodiment, the number of the output bottom BPM pad 211A1 is equal to or different from the number of the input bottom BPM pad 211B1. The second bottom BPM set 311 includes an output bottom BPM 311A and an input bottom BPM 311B. The output bottom BPM 311A and the input bottom BPM 311B are formed in or on the topmost bottom dielectric layer 115. The output bottom BPM 311A includes a plurality of output bottom BPM pad 311A1, the input bottom BPM 311B includes a plurality of input bottom BPM pad 311B1. In the present embodiment, the number of the output bottom BPM pad 311A1 is equal to or different from the number of the input bottom BPM pad 311B1. The third bottom BPM set 411 includes an output bottom BPM 411A and an input bottom BPM 411B. The output bottom BPM 411A and the input bottom BPM 411B are formed in or on the topmost bottom dielectric layer 115. The output bottom BPM 411A includes a plurality of output bottom BPM pad 411A1, the input bottom BPM 411B includes a plurality of input bottom BPM pad 411B1. In the present embodiment, the number of the output bottom BPM pad 411A1 is equal to or different from the number of the input bottom BPM pad 411B1.

As illustrated in FIG. 2A, the output bottom BPM pads 211A1 may arranged in an array of n3×m3, wherein each of n3 and m3 may be a positive integer equal to or greater than one. Similarly, the input bottom BPM pads 211B1 may arranged in an array of n4×m4, wherein each of n4 and m4 may be a positive integer equal to or greater than one. The n3 and n4 may be equal or different in value, and/or m3 and m4 may be equal or different in value. In another embodiment, the output bottom BPM pads 211A1 may be irregularly arranged, and/or the input bottom BPM pads 211B1 may be irregularly arranged.

As illustrated in FIG. 2A, the output bottom BPM pads 311A1 may arranged in an array of n5×m5, wherein each of n5 and m5 may be a positive integer equal to or greater than one. Similarly, the input bottom BPM pads 311B1 may arranged in an array of n6×m6, wherein each of n6 and m6 may be a positive integer equal to or greater than one. The n5 and n6 may be equal or different in value, and/or m5 and m6 may be equal or different in value. In another embodiment, the output bottom BPM pads 311A1 may be irregularly arranged, and/or the input bottom BPM pads 311B1 may be irregularly arranged.

As illustrated in FIG. 2A, the output bottom BPM pads 411A1 may arranged in an array of n7×m7, wherein each of n7 and m7 may be a positive integer equal to or greater than one. Similarly, the input bottom BPM pads 411B1 may arranged in an array of n8×m8, wherein each of n8 and m8 may be a positive integer equal to or greater than one. The n7 and n8 may be equal or different in value, and/or m7 and m8 may be equal or different in value. In another embodiment, the output bottom BPM pads 411A1 may be irregularly arranged, and/or the input bottom BPM pads 411B1 may be irregularly arranged.

As illustrated in FIG. 2B, the first top BPM set 221 includes an input top BPM 221A and an output top BPM 221B, the second top BPM set 321 includes an input top BPM 321A and an output top BPM 321B, and the third top BPM set 421 includes an input top BPM 421A and an output top BPM 421B. The top die 220 further includes a plurality of top BPVs 223, a plurality of top BPVs 323, a plurality of top BPVs 423, a first connection trace 226, a second connection trace 326, a third connection trace 426 and a plurality of top dielectric layers 125. The input top BPM 221A, the output top BPM 221B, the input top BPM 321A, the output top BPM 321B, the input top BPM 421A and the output top BPM 421B are formed in or on the bottommost top dielectric layer 125. The input top BPM 221A includes at least one input top BPM pad 221A1, the output top BPM 121B includes at least one output top BPM pad 221B1. In the present embodiment, the number of the input top BPM pad 221A1 is equal to the number of the output top BPM pad 221B1. In the present embodiment, each input top BPM pad 221A1 is directly bonded to the corresponding output bottom BPM pad 211A1, and each output top BPM pad 221B1 is directly bonded to the corresponding input bottom BPM pad 211B1 by using, for example, hybrid bonding technique. The input top BPM 321A includes a plurality of input top BPM pads 321A1, the output top BPM 321B includes a plurality of output top BPM pads 321B1. In the present embodiment, the number of the input top BPM pad 321A1 is equal to the number of the output top BPM pad 321B1. In the present embodiment, each input top BPM pad 321A1 is directly bonded to the corresponding output bottom BPM pad 311A1, and each output top BPM pad 321B1 is directly bonded to the corresponding input bottom BPM pad 311B1 by using, for example, hybrid bonding technique. The input top BPM 421A includes a plurality of input top BPM pads 421A1, the output top BPM 421B includes a plurality of output top BPM pads 421B1. In the present embodiment, the number of the input top BPM pad 421A1 is equal to the number of the output top BPM pad 421B1. In the present embodiment, each input top BPM pad 421A1 is directly bonded to the corresponding output bottom BPM pad 411A1, and each output top BPM pad 421B1 is directly bonded to the corresponding input bottom BPM pad 411B1 by using, for example, hybrid bonding technique.

As illustrated in FIG. 2B, the first test pad set 212 includes an input test pad 212A and an output test pad 212B. The input test pad 212A and the output test pad 212B are formed in or on the topmost bottom dielectric layer 115. The second test pad set 312 includes an input test pad 312A and an output test pad 312B. The input test pad 312A and the output test pad 312B are formed in or on the topmost bottom dielectric layer 115. The third test pad set 412 includes an input test pad 412A and an output test pad 412B. The input test pad 412A and the output test pad 412B are formed in or on the topmost bottom dielectric layer 115.

As illustrated in FIG. 2B, the first connection trace 216A electrically connects the input test pad 212A with the output bottom BPM 211A through the bottom BPVs 213 and at least one first bottom trace, and the second connection trace 216B electrically connects output test pad 212B with the input bottom BPM 211B through the bottom BPVs 213 and the second bottom trace. The first connection trace 316A electrically connects the input test pad 312A with the output bottom BPM 311A through the bottom BPVs 313 and at least one first bottom trace, and the second connection trace 316B electrically connects output test pad 312B with the input bottom BPM 311B through the bottom BPVs 313 and the second bottom trace. The first connection trace 416A electrically connects the input test pad 412A with the output bottom BPM 411A through the bottom BPVs 413 and at least one first bottom trace, and the second connection trace 416B electrically connects output test pad 412B with the input bottom BPM 411B through the bottom BPVs 413 and at least one second bottom trace.

In an embodiment, the first connection trace 226, the second connection trace 326 and the third connection trace 426 may be formed of aluminum. The top dielectric layer 125 and the bottom dielectric layer 115 may be bonded to each other by using, for example, hybrid bonding technique. The bonding between the dielectric layers of the bottom die 210 and the top die 220 and the bonding between the BPMs of the bottom die 210 and the top die 220 may be performed in the same bonding process.

As illustrated in FIG. 2B, when the WAT probe the first test pad set 212, a first test signal (for example, voltage or current) is send to the input test pad 212A and returned from the output test pad 212B through the first connection trace 216A, the output bottom BPM 211A, the input top BPM 221A, the first connection trace 226, the output top BPM 221B, the input bottom BPM 211B and the second connection trace 216B. The failure mode may be determined by reading a first return signal from the output test pad 212B. Similarly, when the WAT probe the second test pad set 312, a second test signal (for example, voltage or current) is send to the input test pad 312A and returned from the output test pad 312B through the first connection trace 316A, the output bottom BPM 311A, the input top BPM 321A, the first connection trace 326, the output top BPM 321B, the input bottom BPM 311B and the second connection trace 316B. The failure mode may be determined by reading a first return signal from the output test pad 312B.

Similarly, when the WAT probe the second test pad set 412, a third test signal (for example, voltage or current) is send to the input test pad 412A and returned from the output test pad 412B through the first connection trace 416A, the output bottom BPM 411A, the input top BPM 421A, the first connection trace 426, the output top BPM 421B, the input bottom BPM 411B and the second connection trace 416B. The failure mode may be determined by reading a first return signal from the output test pad 412B. The failure mode may be determined according to at least one of the first return signal, the second return signal and the third return signal.

As shown in Table 1 below, if the first return signal presents “open loop”, the second return signal presents “close loop” and the third return signal presents “close loop”, the failure mode is “Defect”. If the first return signal presents “close loop”, the second return signal presents “open loop” and the third return signal presents “close loop”, the failure mode is “Defect”. If the first return signal presents “open loop”, the second return signal presents “open loop” and the third return signal presents “close loop”, the failure mode is “Galvanic”. If the first return signal presents “open loop”, the second return signal presents “open loop” and the third return signal presents “open loop”, the failure mode is “Non-bond”. The “open loop” means that there is no return signal received from the output test pad, and/or the return signal from the output test pad is lower than a preset strength value. The “close loop” means that there is the return signal received from the output test pad, and/or the return signal by the output test pad is higher than the preset strength value.

TABLE 1

| | failure mode | | | |
|---|---|---|---|---|
| return signal | Defect | | Galvanic | Non-bond |
| first return signal | open | close | open | open |
| (output test pad 212B) | | | | |
| second return signal | close | open | open | open |
| (output test pad 312B) | | | | |
| third return signal | close | close | close | open |
| (output test pad 412B) | | | | |

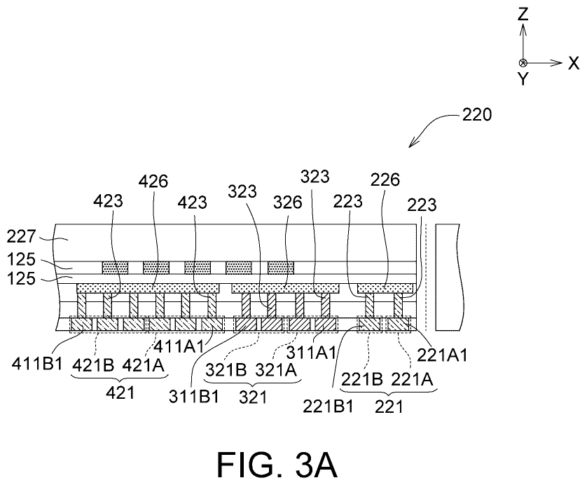

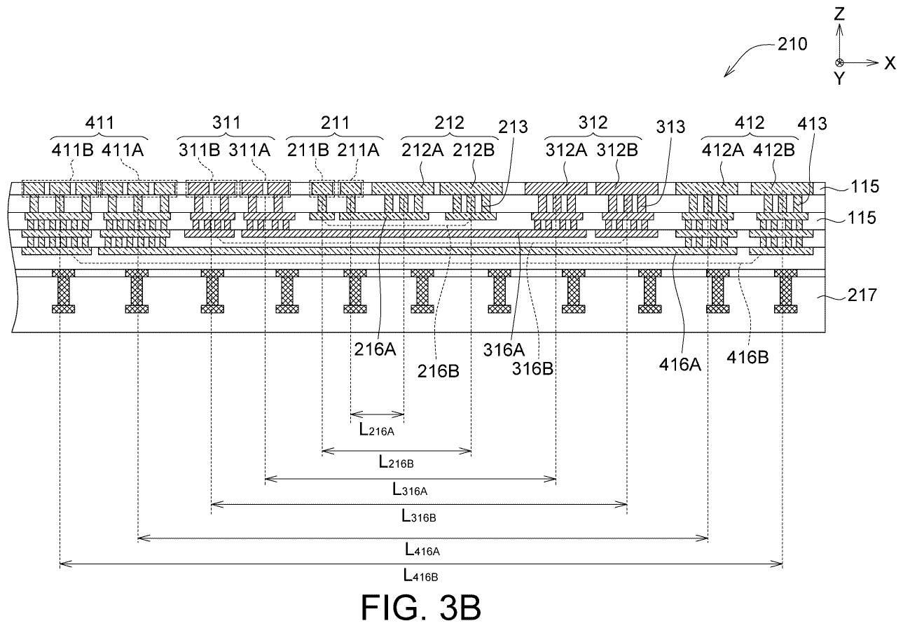

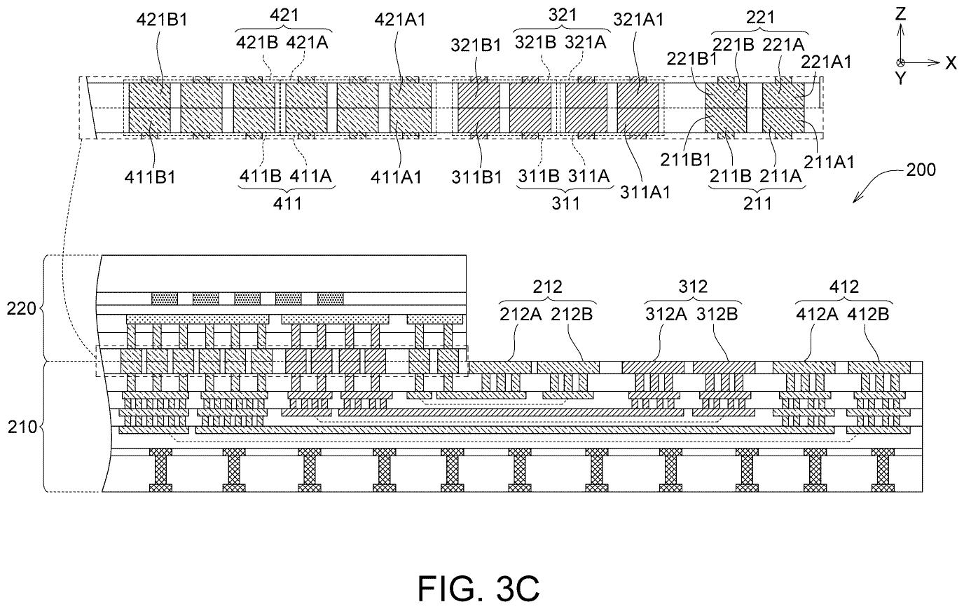

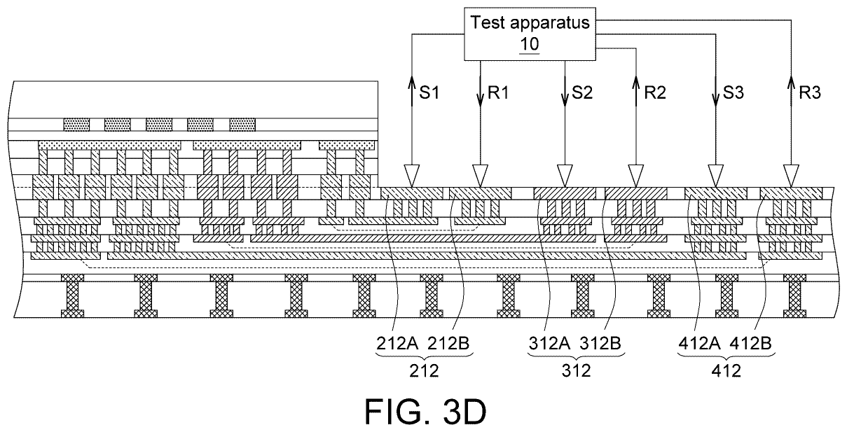

As illustrated in FIG. 2B, for the first test pad set 212 and the first bottom BPM set 211, the output bottom BPM 211A of the first bottom BPM set 211 has a first bottom BPM area along XY plane, and the input test pad 212A of the first test pad set 212 has a first test pad area along XY plane. The first bottom BPM area is the sum of an area of an end surface 211Au, along XY plane, of each output bottom BPM pad 211A1. The first test pad area is an area of an end surface 212Au, along XY plane, of the input test pad 212A. In an embodiment, a first ratio of the first bottom BPM area to the first test pad area may be less than 3/1000, and a first distance L_{216A} (the first distance L_{216A} is illustrated in FIG. 3B) of the input test pad 212A and the output bottom BPM 211A may be greater than 10000 μm. The end surface 212Au of the input test pad 212A is, for example, a rectangle, and the first test pad area of the input test pad 212A is, for example, 3500 μm² (for example, 50 μm×70 μm). The output test pad 212B of the first test pad set 212 includes the features the same as or similar to that of the input test pad 212A of the first test pad set 212. In an embodiment, the first distance L_{216A} (the first distance L_{216A} is illustrated in FIG. 3B) is the distance (in X-axis) from a geometric center of the shape (in XY plane) of the input test pad 212A to a geometric center of the shape (in XY plane) of the output bottom BPM 211A. Similarly, the input bottom BPM 211B of the first bottom BPM set 211 has a first bottom BPM area along XY plane, and the output test pad 212B of the first test pad set 212 has a first test pad area along XY plane. The first bottom BPM area is the sum of an area of an end surface 211Bu, along XY plane, of each input bottom BPM pad 211B1. The first test pad area is an area of an end surface 212Bu, along XY plane, of the output test pad 212B. In an embodiment, a first ratio of the first bottom BPM area of the first bottom BPM set 211 to the first test pad area of the output test pad 212B is less than 3/1000, and a first distance L_{216B} (the first distance L_{216B} is illustrated in FIG. 3B) of the output test pad 212B and the input bottom BPM 211B may be greater than 10000 μm. In an embodiment, the first distance L_{216B} is the distance (in X-axis) from a geometric center of the shape (in XY plane) of the output test pad 212B to a geometric center of the shape (in XY plane) of the input bottom BPM 211B. In addition, depending on the positions of the input test pad 212A and the output test pad 212B of the first test pad set 212, and the output bottom BPM 211A and the input bottom BPM 211B of the first bottom BPM set 211, the first distance L_{216A} may be equal to, less than or greater than the first distance L_{216B}.

As illustrated in FIG. 2B, for the second test pad set 312 and the second bottom BPM set 311, the output bottom BPM 311A of the second bottom BPM set 311 has a second bottom BPM area along XY plane, and the input test pad 312A of the second test pad set 312 has a second test pad area along XY plane. The second bottom BPM area is the sum of an area of an end surface 311Au, along XY plane, of each output bottom BPM pad 311A1. The second test pad area is an area of an end surface 312Au, along XY plane, of the input test pad 312A. In an embodiment, a second ratio of the second bottom BPM area to the second test pad area may be less than 40/1000, and a second distance L_{316A} (the second distance L_{316A} is illustrated in FIG. 3B) of the input test pad 312A and the output bottom BPM 311A may be greater than 10000 μm. The end surface 312Au of the input test pad 312A is, for example, a rectangle, and the second test pad area of the input test pad 312A is, for example, 3500 μm² (for example, 50 μm×70 μm). The output test pad 312B of the second test pad set 312 includes the features the same as or similar to that of the input test pad 312A of the second test pad set 312. In an embodiment, the second distance L_{316A} (the second distance L_{316A} is illustrated in FIG. 3B) is the distance (in X-axis) from a geometric center of the shape or (in XY plane) of the input test pad 312A to a geometric center of the shape or the distribution (in XY plane) of the output bottom BPM 311A. Similarly, the input bottom BPM 311B of the second bottom BPM set 311 has a second bottom BPM area along XY plane, and the output test pad 312B of the second test pad set 312 has a second test pad area along XY plane. The second bottom BPM area is the sum of an area of an end surface 311Bu, along XY plane, of each input bottom BPM pad 311B1. The second test pad area is an area of an end surface 312Bu, along XY plane, of the output test pad 312B. In an embodiment, a second ratio of the second bottom BPM area of the second bottom BPM set 311 to the second test pad area of the output test pad 312B is less than 40/1000, and a second distance L_{316B} (the second distance L_{316B} is illustrated in FIG. 3B) of the output test pad 312B and the input bottom BPM 311B may be greater than 10000 μm. In an embodiment, the second distance L_{316B} is the distance (in X-axis) from a geometric center of the shape (in XY plane) of the output test pad 312B to a geometric center of the shape or the distribution (in XY plane) of the input bottom BPM 311B. In addition, depending on the positions of the input test pad 312A and the output test pad 312B of the second test pad set 312, and the output bottom BPM 311A and the input bottom BPM 311B of the second bottom BPM set 311, the second distance L_{316A} may be equal to, less than or greater than the second distance L_{316B}.

As illustrated in FIG. 2B, for the third test pad set 412 and the third bottom BPM set 411, the output bottom BPM 411A of the third bottom BPM set 411 has a third bottom BPM area along XY plane, and the input test pad 412A of the third test pad set 412 has a third test pad area along XY plane. The third bottom BPM area is the sum of an area of an end surface 411Au, along XY plane, of each output bottom BPM pad 411A1. The third test pad area is an area of an end surface 412Au, along XY plane, of the input test pad 412A. In an embodiment, a third ratio of the third bottom BPM area to the second test pad area may be greater than 50/1000, and a third distance L_{416A} (the third distance L_{416A} is illustrated in FIG. 3B) of the input test pad 412A and the output bottom BPM 411A may be greater than 10000 μm. The end surface 412Au of the input test pad 412A is, for example, a rectangle, and the third test pad area of the input test pad 412A is, for example, 3500 μm² (for example, 50 μm×70 μm). The output test pad 412B of the third test pad set 412 includes the features the same as or similar to that of the input test pad 412A of the third test pad set 412. In an embodiment, the third distance L_{416A} (the third distance L_{416A} is illustrated in FIG. 3B) is the distance (in X-axis) from a geometric center of the shape or (in XY plane) of the input test pad 412A to a geometric center of the shape or the distribution (in XY plane) of the output bottom BPM 411A. Similarly, the input bottom BPM 411B of the third bottom BPM set 411 has a third bottom BPM area along XY plane, and the output test pad 412B of the third test pad set 412 has a third test pad area along XY plane. The third bottom BPM area is the sum of an area of an end surface 411Bu, along XY plane, of each input bottom BPM pad 411B1. The third test pad area is an area of an end surface 412Bu, along XY plane, of the output test pad 412B. In an embodiment, a third ratio of the third bottom BPM area of the third bottom BPM set 411 to the third test pad area of the output test pad 412B is greater than 50/1000, and a third distance L_{416B} (the third distance L_{416B} is illustrated in FIG. 3B) of the output test pad 412B and the input bottom BPM 411B may be greater than 10000 μm. In an embodiment, the third distance L_{416B} is the distance (in X-axis) from a geometric center of the shape (in XY plane) of the output test pad 412B to a geometric center of the shape or the distribution (in XY plane) of the input bottom BPM 411B. In addition, depending on the positions of the input test pad 412A and the output test pad 412B of the third test pad set 412, and the output bottom BPM 411A and the input bottom BPM 411B of the third bottom BPM set 411, the third distance L_{416A} may be equal to, less than or greater than the third distance L_{416B}.

In an embodiment, at least two of the first test pad area, the second test pad area and the third test pad area may be equal.

In an embodiment, the first bottom BPM area A_{211A} of the output bottom BPM 211A of the first bottom BPM set 211, the second bottom BPM area A_{311A} of the output bottom BPM 311A of the second bottom BPM set 311, the third bottom BPM area A_{411A} of the output bottom BPM 411A of the third bottom BPM set 411 and the first test pad area A_{212A} of the input test pad 212A of the first test pad set 212 may satisfy formulas (1) and (2) below. In addition, the first test pad area A_{312A} in formulas (1) and (2) may be replaced by the second test pad area of the output test pad 312A of the second test pad set 312 or the third test pad area of the output test pad 412A of the third test pad set 412.

$${A}_{211 A} < {A}_{311 A} < {A}_{411 A} < {A}_{212 A} \qquad ( 1 )$$

$${A}_{211 A} = {A}_{311 A} < {A}_{411 A} < {A}_{212 A} \qquad ( 2 )$$

The first bottom BPM area A_{211B} of the input bottom BPM 211B of the first bottom BPM set 211, the second bottom BPM area A_{311B} of the input bottom BPM 311B of the second bottom BPM set 311, the third bottom BPM area A_{411B} of the input bottom BPM 411B of the third bottom BPM set 411 and the first test pad area A_{212B} of the output test pad 212B of the first test pad set 212 may satisfy the formulas the same as or similar to formulas (1) and (2) above.

As shown in formulas (1) and (2) above, the first bottom BPM area A_{211A} (or the first bottom BPM area A_{211B}) of the first bottom BPM set 211 may be equal to or less than the second bottom BPM area A_{311A} (or the second bottom BPM area A_{311B}) of the second bottom BPM set 311, and/or the third bottom BPM area A_{411A} (or the third bottom BPM area A_{411B}) of the third bottom BPM set 411 may be greater than the first bottom BPM area A_{211A} (or the first bottom BPM area A_{211B}) of the first bottom BPM set 211 and the second bottom BPM area A_{311A} (or the second bottom BPM area A_{311B}) of the second bottom BPM set 311. In addition, the first test pad area A_{212A} (or the first test pad area A_{212B}) of the first test pad set 212 may be greater than the first bottom BPM area A_{211A} (or the first bottom BPM area A_{211B}) of the first bottom BPM set 211, the second bottom BPM area A_{311A} (or the second bottom BPM area A_{311B}) of the second bottom BPM set 311 and the third bottom BPM area A_{411A} (or the third bottom BPM area A_{411B}) of the third bottom BPM set 411.

In an embodiment, the first distance L_{216A} (or the first distance L_{216B}), the second distance L_{316A} (or the second distance L_{316B}) and the third distance L_{416A} (or the third distance L_{416B}) may satisfy formula (3) below.

$${L}_{216 A} ≅ {L}_{316 A} ≅ {L}_{416 A} \geq 10000 μm \qquad ( 3 )$$

Due to the design of the ratio, the area and/or the distance, the failure mode (at least including the defect, the galvanic and the non-bond) may be determined by reading and analyzing the first return signal from the output test pad 212B of the first test pad set 212, the second return signal from the output test pad 312B of the second test pad set 312 and the third return signal from the output test pad 312B of the third test pad set 412.

Furthermore, the first bottom BPM set 211 may be configured for the defect mode, the galvanic mode and the non-bond mode, the second bottom BPM set 311 may be configured for the defect mode and the galvanic mode, and the third bottom BPM set 411 may be configured for the non-bond mode. The third bottom BPM set 411 has a lot of BPM in parallel with larger detection area, and thus it is capable of detecting the non-bond mode, if all BPMs are open. The greater the ratio of the bottom BPM area to the test pad area is, the easier the galvanic happens. Furthermore, the first and second bottom BPM set 211, 311 is capable of detecting galvanic mode. The greater the distance of the test pad and the bottom BPM is, the easier the galvanic happens. Furthermore, in the present embodiment, the distance of the test pad and the bottom BPM is greater than 10000 μm, and thus it is capable of detecting the galvanic.

Referring to FIGS. 3A to 3D, FIGS. 3A to 3D illustrate test processes of a bonding failure test method of the semiconductor device 200 in FIG. 2B.

As illustrated in FIG. 3A, the top die 220 is provided. For example, at least one top die 220 is formed by singulation process (for example, sawing, etc.). The top die 220 includes a silicon base 227, a plurality of top dielectric layers 125, the first top BPM set 221, the second top BPM set 321, the third top BPM set 421, a plurality of top BPVs 223, a plurality of top BPVs 323, a plurality of top BPVs 423, the first connection trace 226, the second connection trace 326, the third connection trace 426. The top dielectric layers 125 are stacked on the silicon base 227. The silicon base 227 is, for example, a portion of silicon wafer. The top dielectric layer 125 may be formed of, for example, oxide, etc. The first connection trace 226, the second connection trace 326 and the third connection trace 426 are formed in the corresponding top dielectric layer 125. The first top BPM set 221, the second top BPM set 321 and the third top BPM set 421 are formed in the bottommost top dielectric layer 125 and exposed from a bottom surface of the bottommost top dielectric layer 125. The top BPVs 223 are formed in the top dielectric layer 125 and connect the first connection trace 226 with the first top BPM set 221, the top BPVs 323 are formed in the top dielectric layer 125 and connect the second connection trace 326 with the second top BPM set 321, and the top BPVs 423 are formed in the top dielectric layer 125 and connect the third connection trace 426 with the third top BPM set 421.

As illustrated in FIG. 3B, the bottom die 210, wherein the bottom die 210 includes a silicon base 217, a plurality of the bottom dielectric layers 115, the first test pad set 212, the second test pad set 312, the third test pad set 412, the first bottom BPM set 211 electrically connected with the first test pad set 212, the second bottom BPM set 311 electrically connected with the second test pad set 312, the third bottom BPM set 411 electrically connected with the third test pad set 412, the bottom BPVs 213, the bottom BPVs 313, the bottom BPVs 413, the first connection trace 216A, the second connection trace 216B, the first connection trace 316A, the second connection trace 316B, the first connection trace 416A and the second connection trace 416B. The bottom dielectric layers 115 are stacked to the silicon base 217. The silicon base 217 is, for example, a portion of silicon wafer. The first connection trace 216A connects the input test pad 212A of the first test pad set 212 with the output bottom BPM 211A of the first bottom BPM set 211 through the bottom BPVs 213. The first connection trace 216B is formed in the corresponding bottom dielectric layer 115 and connects the output test pad 212B of the first test pad set 212 with the input bottom BPM 211B of the first bottom BPM set 211 through the bottom BPVs 213. The second connection trace 316A is formed in the corresponding bottom dielectric layer 115 and connects the input test pad 312A of the second test pad set 312 with the output bottom BPM 311A of the second bottom BPM set 311 through the bottom BPVs 313. The second connection trace 316B connects the output test pad 312B of the second test pad set 312 with the input bottom BPM 311B of the second bottom BPM set 311 through the bottom BPVs 313. The third connection trace 416A is formed in the corresponding bottom dielectric layer 115 and connects the input test pad 412A of the third test pad set 412 with the output bottom BPM 411A of the third bottom BPM set 411 through the bottom BPVs 413. The third connection trace 416B connects the output test pad 412B of the third test pad set 412 with the input bottom BPM 411B of the third bottom BPM set 411 through the bottom BPVs 413. The first test pad set 212, the second test pad set 312, the third test pad set 412, the first test pad set 212, the second test pad set 312 and the third test pad set 412 are formed on the topmost bottom dielectric layer 115 and exposed from an upper surface of the topmost bottom dielectric layer 115.

As illustrated in FIG. 3C, the top die 220 is bonded to the bottom die 210 by, for example, hybrid bonding technique, wherein the first top BPM set 221 is directly bonded to the first bottom BPM set 211, the second top BPM set 321 is directly bonded to the second bottom BPM set 311 and the third top BPM set 421 is directly bonded to the third bottom BPM set 411.

In the present embodiment, once the top die 220 is bonded to the bottom die 210, an electrical test may be performed on the boned top die 220 and bottom die 210. Furthermore, in the present embodiment, the electrical test may be performed on the boned top die 220 and bottom die 210 before a process, such as MCG (mechanical chemical grinding) process, a TSV (through silicon via) process, a C4 process, a WLCP (wafer level chip scale package) test, an on substrate (oS) process, a final test (FT), etc. Thus, the failure mode may be detected early.

As illustrated in FIG. 3D, the first test pad set 212 is probed to receive the first return signal R1 by a test apparatus 10, the second test pad set 312 is probed to receive the second return signal R2 by the test apparatus 10, and the third test pad set 412 is probed to receive the second return signal R3 by the test apparatus 10.

The test apparatus 10 is, for example, the WAT. The test apparatus 10 applies a first test signal S1 (for example, voltage or current) to the input test pad 212A and receive the first return signal R1 from the output test pad 212B. The test apparatus 10 applies a second test signal S2 (for example, voltage or current) to the input test pad 312A and receive the second return signal R2 from the output test pad 312B. The test apparatus 10 applies a third test signal S3 (for example, voltage or current) to the input test pad 412A and receive the third return signal R3 from the output test pad 412B.

Then, the test apparatus 10 may determine the failure mode of the semiconductor device 200 according to the first return signal R1, the second return signal R2 and the third return signal R3 as shown in Table 1 above. For example, according to Table 1 above, if the first return signal R1 presents an open loop, the second return signal R2 presents a close loop, the third return signal R3 presents the close loop, the test apparatus 10 may determine that the failure mode of the semiconductor device 200 belong the defect mode. If the first return signal R1 presents the open loop, the second return signal R2 presents the open loop, the third return signal R3 presents the close loop, the test apparatus 10 may determine that the failure mode of the semiconductor device 200 belong the galvanic mode. If the first return signal R1 presents the open loop, the second return signal R2 presents the open loop, the third return signal R3 presents the open loop, the test apparatus 10 may determine that the failure mode of the semiconductor device belong the non-bond mode.

After the bonding failure test is completed, the structure in FIG. 3D may be singulated by, for example, sawing, etc., to form at least one semiconductor device 200 in FIG. 2B.

The semiconductor device 100 may be formed by the steps the same as or similar to that of the semiconductor device 200, and they will not be repeated here.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes a bottom die, a top die bonded to each other and a plurality of test groups, wherein the test groups are formed on/in the bottom die and the top die. Each test group has a test pad set and a bottom BPM set. Through design of the ratio of the area of the bottom BPM set to the area of the bottom BPM set, and the design of the area of the bottom BPM set and/or the area of the bottom BPM set, the failure mode (at least including the defect, the galvanic and the non-bond) may be detected or determined.
Example embodiment 1: a semiconductor device includes a bottom die and a top die. The bottom die includes a first test pad set, a second test pad set, a third test pad set, a first bottom BPM set electrically connected with the first test pad set, a second bottom BPM set electrically connected with the second test pad set, and a third bottom BPM set electrically connected with the third test pad set. The top die includes a first top BPM set bonded to the first bottom BPM set, a second top BPM set bonded to the second bottom BPM set, and a third top BPM set bonded to the third bottom BPM set. The first test pad set has a test pad area, the first bottom BPM set has a first bottom BPM area, the second bottom BPM set has a second bottom BPM area, and the third bottom BPM set has a third bottom BPM area. The test pad area is greater than the first bottom BPM area, the second bottom BPM area and the third bottom BPM area, and the third bottom BPM area is greater than the first bottom BPM area and the second bottom BPM area.
Example embodiment 2 based on Example embodiment 1: there is a first distance between the first test pad set and the first bottom BPM set, there is a second distance between the second test pad set and the second bottom BPM set, there is a third distance between the third test pad set and the third bottom BPM set, and the first distance, the second distance and the third distance are substantially equal. The first distance, the second distance and the third distance each is greater than 10000 micrometers.
Example embodiment 3 based on Example embodiment 1: the first test pad set includes an input test pad and an output test pad, the first bottom BPM set includes an output bottom BPM pad electrically connected with the input test pad and an input bottom BPM pad electrically connected with the output test pad, the input test pad and the output test pad each has the test pad area, and the output bottom BPM pad and the input bottom BPM pad each has the first bottom BPM area.
Example embodiment 4 based on Example embodiment 1: the first test pad set includes an input test pad and an output test pad, the first bottom BPM set includes at least one input bottom BPM pad and at least one output bottom BPM pad, the input test pad is electrically connected with the at least one output bottom BPM pad, the output test pad is electrically connected with the at least one input bottom BPM pad.
Example embodiment 5 based on Example embodiment 1: the first bottom BPM set, the second bottom BPM set and the third bottom BPM set each includes at least one bottom BPM pad, the number of the at least one bottom BPM pad of the third bottom BPM set is more than the number of the at least one bottom BPM pad of the second bottom BPM set, and the number of the at least one bottom BPM pad of the second bottom BPM set is more than the number of the at least one bottom BPM pad of the first bottom BPM set.
Example embodiment 6 based on Example embodiment 1: the first bottom BPM set, the second bottom BPM set and the third bottom BPM set each includes at least one bottom BPM pad, the number of the at least one bottom BPM pad of the third bottom BPM set is more than the number of the at least one bottom BPM pad of the second bottom BPM set, and the number of the at least one bottom BPM pad of the second bottom BPM set is equal to the number of the at least one bottom BPM pad of the first bottom BPM set.
Example embodiment 7 based on Example embodiment 1: a first ratio of the first bottom BPM area to the test pad area is equal to or less than 3/1000.
Example embodiment 8 based on Example embodiment 1: a second ratio of the second bottom BPM area to the test pad area is equal to or less than 40/1000.
Example embodiment 9 based on Example embodiment 1: a third ratio of the third bottom BPM area to the test pad area is equal to or greater than 50/1000.
Example embodiment 10: a semiconductor device includes a bottom die and a top die. The includes a first test pad set, a second test pad set, a first bottom BPM set electrically connected with the first test pad set, and a second bottom BPM set electrically connected with the second test pad set. The top die includes a first top BPM set bonding to the first bottom BPM set, and a second top BPM set bonding to the second bottom BPM set. The first test pad set has a test pad area, the first bottom BPM set has a first bottom BPM area, and the second bottom BPM set has a second bottom BPM area. The test pad area is greater than the first bottom BPM area and the second bottom BPM area, and the first bottom BPM area is equal to or less than the second bottom BPM area.
Example embodiment 11 based on Example embodiment 10: there is a first distance between the first test pad set and the first bottom BPM set, there is a second distance between the second test pad set and the second bottom BPM set, and the first distance and the second distance are substantially equal. The first distance and the second distance each is greater than 10000 micrometers.
Example embodiment 12 based on Example embodiment 10: the first test pad set includes an input test pad and an output test pad, the first bottom BPM set includes an output bottom BPM pad and an input bottom BPM pad, the input test pad and the output test pad each has the test pad area, and the output bottom BPM pad and the input bottom BPM pad each has the first bottom BPM area.
Example embodiment 13 based on Example embodiment 10: the first test pad set includes an input test pad and an output test pad, the first bottom BPM set includes at least one input bottom BPM pad and at least one output bottom BPM pad, the input test pad is electrically connected with the at least one output bottom BPM pad, the output test pad is electrically connected with the at least one input bottom BPM pad.
Example embodiment 14 based on Example embodiment 10: the first bottom BPM set and the second bottom BPM set each includes at least one bottom BPM pad, and the number of the at least one bottom BPM pad of the second bottom BPM set is more than the number of the at least one bottom BPM pad of the first bottom BPM set.
Example embodiment 15 based on Example embodiment 10: the first bottom BPM set and the second bottom BPM set each includes at least one bottom BPM pad, and the number of the at least one bottom BPM pad of the second bottom BPM set is equal to the number of the at least one bottom BPM pad of the first bottom BPM set.
Example embodiment 16 based on Example embodiment 10: a first ratio of the first bottom BPM area to the test pad area is equal to or less than 3/1000, and a second ratio of the second bottom BPM area to the test pad area is equal to or less than 40/1000.
Example embodiment 17: a bonding failure test method, suitable for testing a failure mode of a semiconductor device, including the following steps: providing a bottom die, wherein the bottom die includes a first test pad set, a second test pad set and a third test pad set, a first bottom BPM set electrically connected with the first test pad set, a second bottom BPM set electrically connected with the second test pad set, a third bottom BPM set electrically connected with the third test pad set, the first test pad set has a test pad area, the first bottom BPM set has a first bottom BPM area, the second bottom BPM set has a second bottom BPM area, the third bottom BPM set has a third bottom BPM area, the test pad area is greater than the first bottom BPM area, the second bottom BPM area and the third bottom BPM area, and the third bottom BPM area is greater than the first bottom BPM area and the second bottom BPM area; providing a top die, wherein the top die includes a first top BPM set, a second top BPM set and a third top BPM set; bonding the bottom die with the top die, wherein the first top BPM set is bonded to the first bottom BPM set, the second top BPM set is bonded to the second bottom BPM set and the third top BPM set is bonded to the third bottom BPM set; probing the first test pad set to receive a first return signal by a test apparatus; probing the second test pad set to receive a second return signal by the test apparatus; probing the third test pad set to receive a third return signal by the test apparatus; and determining a failure mode of the semiconductor device according to the first return signal, the second return signal and the third return signal.
Example embodiment 18 based on Example embodiment 17: in determining the failure mode of the semiconductor device according to the first return signal, the second return signal and the third return signal, the bonding failure test method further includes: determining that the failure mode of the semiconductor device belong a defect mode if the first return signal presents an open loop, the second return signal presents a close loop, the third return signal presents the close loop.
Example embodiment 19 based on Example embodiment 17: in determining the failure mode of the semiconductor device according to the first return signal, the second return signal and the third return signal, the bonding failure test method further includes: determining that the failure mode of the semiconductor device belong a galvanic mode if the first return signal presents the open loop, the second return signal presents the open loop, the third return signal presents the close loop.
Example embodiment 20 based on Example embodiment 17: in determining the failure mode of the semiconductor device according to the first return signal, the second return signal and the third return signal, the bonding failure test method further includes: determining that the failure mode of the semiconductor device belong a non-bond mode if the first return signal presents the open loop, the second return signal presents the open loop, the third return signal presents the open loop.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a bottom die, comprising:
a first test pad set;
a second test pad set;
a third test pad set;
a first bottom bonding pad metal (BPM) set electrically connected with the first test pad set;
a second bottom BPM set electrically connected with the second test pad set; and
a third bottom BPM set electrically connected with the third test pad set;
a top die, comprising:
a first top BPM set bonded to the first bottom BPM set;
a second top BPM set bonded to the second bottom BPM set; and
a third top BPM set bonded to the third bottom BPM set;
wherein the first test pad set has a test pad area, the first bottom BPM set has a first bottom BPM area, the second bottom BPM set has a second bottom BPM area, and the third bottom BPM set has a third bottom BPM area;
wherein the test pad area is greater than the first bottom BPM area, the second bottom BPM area and the third bottom BPM area, and the third bottom BPM area is greater than the first bottom BPM area and the second bottom BPM area.

2. The semiconductor device according to claim 1, wherein there is a first distance between the first test pad set and the first bottom BPM set, there is a second distance between the second test pad set and the second bottom BPM set, there is a third distance between the third test pad set and the third bottom BPM set, and the first distance, the second distance and the third distance are substantially equal;
wherein the first distance, the second distance and the third distance each is greater than 10000 micrometers.

3. The semiconductor device according to claim 1, wherein the first test pad set comprises an input test pad and an output test pad, the first bottom BPM set comprises an output bottom BPM pad electrically connected with the input test pad and an input bottom BPM pad electrically connected with the output test pad, the input test pad and the output test pad each has the test pad area, and the output bottom BPM pad and the input bottom BPM pad each has the first bottom BPM area.

4. The semiconductor device according to claim 1, wherein the first test pad set comprises an input test pad and an output test pad, the first bottom BPM set comprises at least one input bottom BPM pad and at least one output bottom BPM pad, the input test pad is electrically connected with the at least one output bottom BPM pad, the output test pad is electrically connected with the at least one input bottom BPM pad.

5. The semiconductor device according to claim 1, wherein the first bottom BPM set, the second bottom BPM set and the third bottom BPM set each comprises at least one bottom BPM pad, the number of the at least one bottom BPM pad of the third bottom BPM set is more than the number of the at least one bottom BPM pad of the second bottom BPM set, and the number of the at least one bottom BPM pad of the second bottom BPM set is more than the number of the at least one bottom BPM pad of the first bottom BPM set.

6. The semiconductor device according to claim 1, wherein the first bottom BPM set, the second bottom BPM set and the third bottom BPM set each comprises at least one bottom BPM pad, the number of the at least one bottom BPM pad of the third bottom BPM set is more than the number of the at least one bottom BPM pad of the second bottom BPM set, and the number of the at least one bottom BPM pad of the second bottom BPM set is equal to the number of the at least one bottom BPM pad of the first bottom BPM set.

7. The semiconductor device according to claim 1, wherein a first ratio of the first bottom BPM area to the test pad area is equal to or less than 3/1000.

8. The semiconductor device according to claim 1, wherein a second ratio of the second bottom BPM area to the test pad area is equal to or less than 40/1000.

9. The semiconductor device according to claim 1, wherein a third ratio of the third bottom BPM area to the test pad area is equal to or greater than 50/1000.

10. A semiconductor device, comprising:
a bottom die, comprising:
a first test pad set;
a second test pad set;
a first bottom BPM set electrically connected with the first test pad set; and
a second bottom BPM set electrically connected with the second test pad set;
a top die, comprising:
a first top BPM set bonding to the first bottom BPM set; and
a second top BPM set bonding to the second bottom BPM set;
wherein the first test pad set has a test pad area, the first bottom BPM set has a first bottom BPM area, and the second bottom BPM set has a second bottom BPM area;
wherein the test pad area is greater than the first bottom BPM area and the second bottom BPM area, and the first bottom BPM area is equal to or less than the second bottom BPM area.

11. The semiconductor device according to claim 10, wherein there is a first distance between the first test pad set and the first bottom BPM set, there is a second distance between the second test pad set and the second bottom BPM set, and the first distance and the second distance are substantially equal;
wherein the first distance and the second distance each is greater than 10000 micrometers.

12. The semiconductor device according to claim 10, wherein the first test pad set comprises an input test pad and an output test pad, the first bottom BPM set comprises an output bottom BPM pad and an input bottom BPM pad, the input test pad and the output test pad each has the test pad area, and the output bottom BPM pad and the input bottom BPM pad each has the first bottom BPM area.

13. The semiconductor device according to claim 10, wherein the first test pad set comprises an input test pad and an output test pad, the first bottom BPM set comprises at least one input bottom BPM pad and at least one output bottom BPM pad, the input test pad is electrically connected with the at least one output bottom BPM pad, the output test pad is electrically connected with the at least one input bottom BPM pad.

14. The semiconductor device according to claim 10, wherein the first bottom BPM set and the second bottom BPM set each comprises at least one bottom BPM pad, and the number of the at least one bottom BPM pad of the second bottom BPM set is more than the number of the at least one bottom BPM pad of the first bottom BPM set.

15. The semiconductor device according to claim 10, wherein the first bottom BPM set and the second bottom BPM set each comprises at least one bottom BPM pad, and the number of the at least one bottom BPM pad of the second bottom BPM set is equal to the number of the at least one bottom BPM pad of the first bottom BPM set.

16. The semiconductor device according to claim 10, wherein a first ratio of the first bottom BPM area to the test pad area is equal to or less than 3/1000, and a second ratio of the second bottom BPM area to the test pad area is equal to or less than 40/1000.

17. A bonding failure test method, suitable for testing a failure mode of a semiconductor device, comprising:
providing a top die, wherein the top die comprises a first top BPM set, a second top BPM set and a third top BPM set;
providing a bottom die, wherein the bottom die comprises a first test pad set, a second test pad set and a third test pad set, a first bottom BPM set electrically connected with the first test pad set, a second bottom BPM set electrically connected with the second test pad set, a third bottom BPM set electrically connected with the third test pad set, the first test pad set has a test pad area, the first bottom BPM set has a first bottom BPM area, the second bottom BPM set has a second bottom BPM area, the third bottom BPM set has a third bottom BPM area, the test pad area is greater than the first bottom BPM area, the second bottom BPM area and the third bottom BPM area, and the third bottom BPM area is greater than the first bottom BPM area and the second bottom BPM area;
bonding the bottom die with the top die, wherein the first top BPM set is bonded to the first bottom BPM set, the second top BPM set is bonded to the second bottom BPM set and the third top BPM set is bonded to the third bottom BPM set;
probing the first test pad set to receive a first return signal by a test apparatus;
probing the second test pad set to receive a second return signal by the test apparatus;
probing the third test pad set to receive a third return signal by the test apparatus; and
determining a failure mode of the semiconductor device according to the first return signal, the second return signal and the third return signal.

18. The bonding failure test method according to claim 17, wherein in determining the failure mode of the semiconductor device according to the first return signal, the second return signal and the third return signal, the bonding failure test method further comprising:
determining that the failure mode of the semiconductor device belong a defect mode if the first return signal presents an open loop, the second return signal presents a close loop, the third return signal presents the close loop.

19. The bonding failure test method according to claim 17, wherein in determining the failure mode of the semiconductor device according to the first return signal, the second return signal and the third return signal, the bonding failure test method further comprising:
determining that the failure mode of the semiconductor device belong a galvanic mode if the first return signal presents the open loop, the second return signal presents the open loop, the third return signal presents the close loop.

20. The bonding failure test method according to claim 17, wherein in determining the failure mode of the semiconductor device according to the first return signal, the second return signal and the third return signal, the bonding failure test method further comprising:
determining that the failure mode of the semiconductor device belong a non-bond mode if the first return signal presents the open loop, the second return signal presents the open loop, the third return signal presents the open loop.
